(19) United States
(12) Patent Application Publication
(10) Pub. No.: US 2010/0251077 A1
(43) Pub. Date: Sep. 30, 2010

(54) STORAGE DEVICE AND DATA STORAGE SYSTEM INCLUDING OF THE SAME

(75) Inventors: Yong June Kim, Seoul (KR); Jae Hong Kim, Seoul (KR); Jun Jin Kong, Yongin-si (KR); Hong Rak Son, Anyang-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/729,285

(22) Filed: Mar. 23, 2010

(30) Foreign Application Priority Data
Mar. 25, 2009 (KR) 10-2009-0025168

(51) Int. Cl. G06F 12/02; H03M 13/05; G06F 11/10

(52) U.S. Cl. 714/773; 711/103; 711/E12.008; 714/E11.032

(57) ABSTRACT

A storage device includes a controller unit and a memory cell array. The controller unit is for outputting data through a first data path or a second data path according to a property of externally supplied input data. The memory cell array includes a first memory and a second memory, and receives and stores the data from the controller unit output through the first and second data paths. The first memory has a different memory cell structure than the second memory.

### CROSS-REFERENCE TO RELATED APPLICATIONS

A claim of priority under 35 U.S.C. §119 is made to Korean Patent Application No. 10-2009-0025168, filed Mar. 25, 2009, in the Korean Intellectual Property Office, the disclosure of which is incorporated herein in its entirety by reference.

### BACKGROUND

The inventive concepts described herein generally relate to storage devices, and more particularly, to data storage devices, and to data storage systems including of the same.

Non-volatile memory devices are utilized in a wide variety of application, such as MP3 players, digital cameras, mobile phones, camcorders, flash cards and solid state drive/disk (SSD) devices.

Generally, non-volatile memory devices can be classified as either signal level cell (SLC) devices which store a single bit of data per memory cell, and multi-level cell (MLC) devices which store two or more bits per memory cell. There are operational tradeoffs between SLC and MLC. That is, SLC typically exhibits better performance and reliability characteristics, while MLC is typically more competitive in terms of storage cost per unit of data. Thus, while non-volatile memory devices employing MLC cells are capable of storing large quantities of data at relative low cost, the speed and reliability of such devices are generally less favorable than SLC non-volatile memory devices.

### SUMMARY

According to an example embodiment of the inventive concepts, a storage device is provided which includes a controller unit and a memory cell array. The controller unit is for outputting data through a first data path or a second data path according to a property of externally supplied input data. The memory cell array includes a first memory and a second memory, and receives and stores the data from a controller unit output through the first and second data paths. The first memory has a different memory cell structure than the second memory.

According to another example embodiment of the inventive concepts, a storage system is provided which includes a data bus, a storage device, a central processing unit, and an interface. The storage device includes a controller unit and a memory cell array. The controller unit is for outputting data through a first data path or a second data path according to a property of externally supplied input data. The memory cell array includes a first memory and a second memory, and receives and stores the data from the controller unit output through the first and second data paths. The first memory has a different memory cell structure than the second memory.

### BRIEF DESCRIPTION OF THE DRAWINGS

These and/or other aspects and advantages of the inventive concepts will become apparent and more readily appreciated from the description of the embodiments that follows, taken in conjunction with the accompanying drawings, in which:

FIG. 1 is a schematic block diagram of a storage device according to an example embodiment of the inventive concepts;

FIG. 2 is a schematic sectional diagram of a first memory illustrated in FIG. 1 according to an example embodiment of the inventive concepts;

FIG. 3 is a schematic sectional diagram of a second memory illustrated in FIG. 1 according to an example embodiment of the inventive concepts;

FIG. 4 is an operation flowchart of the storage device illustrated in FIG. 1 according to an example embodiment of the inventive concepts; and

FIG. 5 is a schematic block diagram of a data storage system including the storage device illustrated in FIG. 1.

### DETAILED DESCRIPTION OF EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

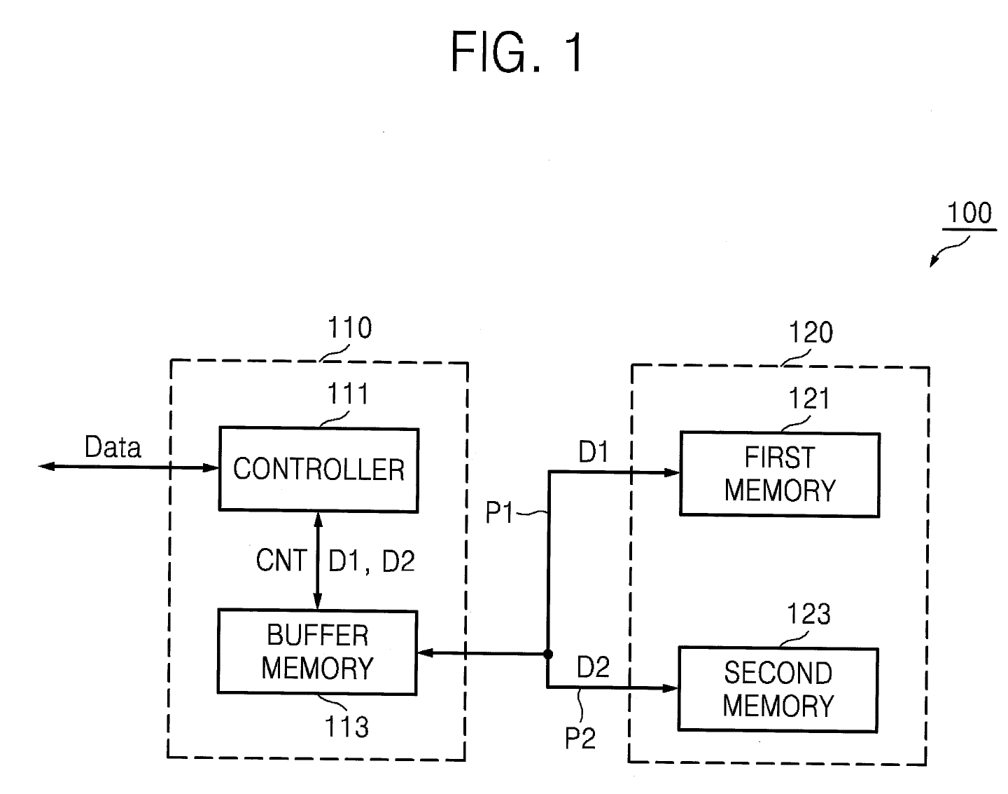

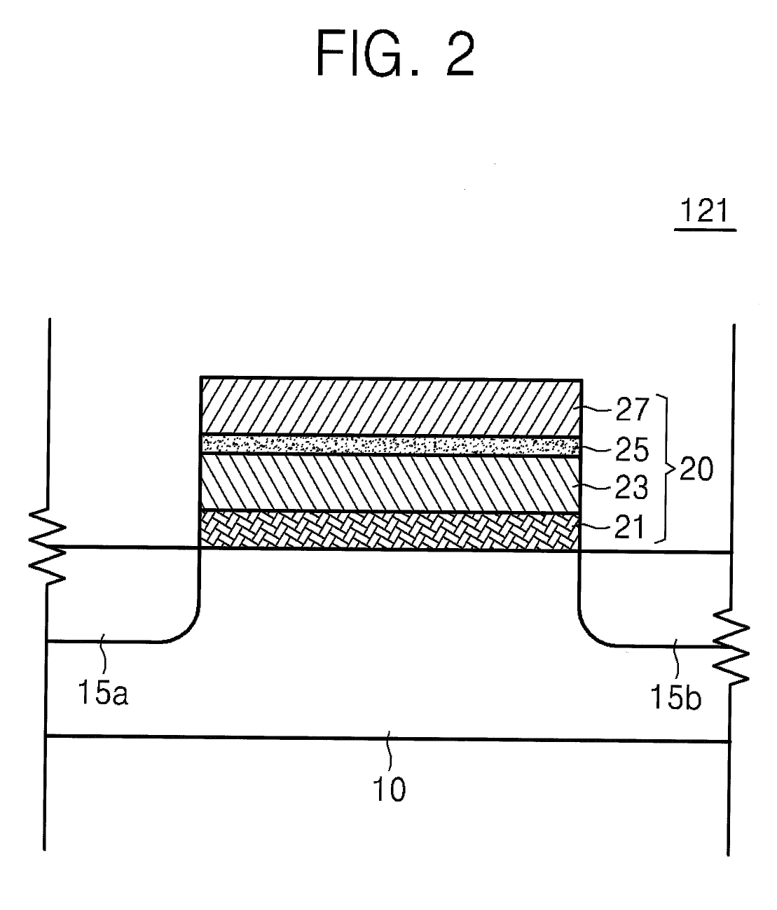

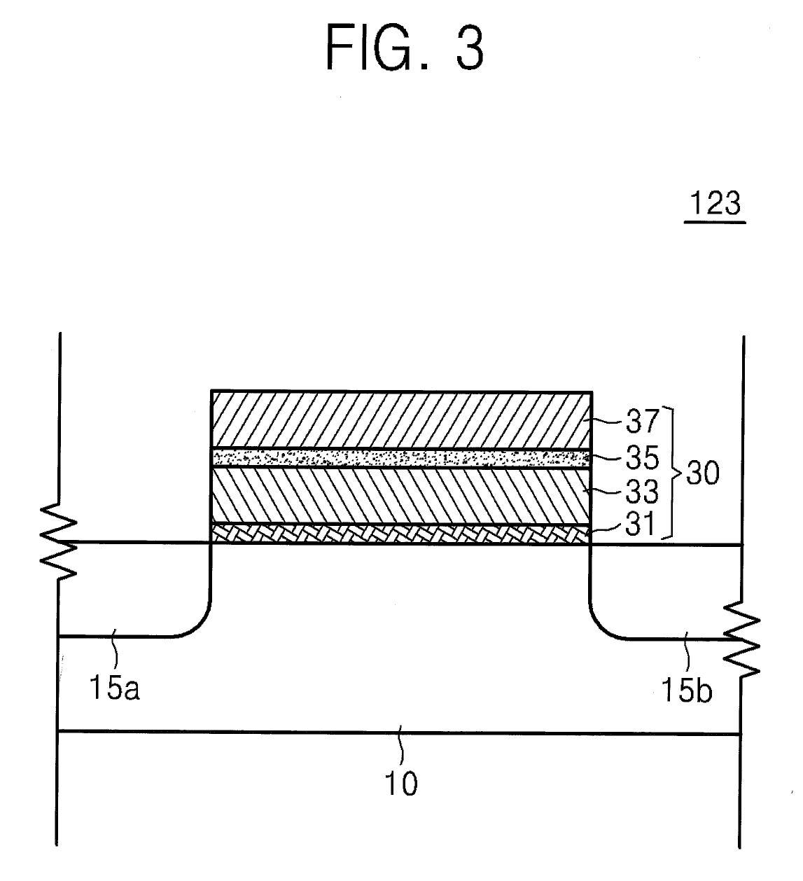

FIG. 1 is a schematic block diagram of a storage device according to an example embodiment of inventive concepts, FIG. 2 is a schematic sectional diagram of a first memory illustrated in FIG. 1 according to an example embodiment of inventive concepts, and FIG. 3 is a schematic sectional diagram of a second memory illustrated in FIG. 1 according to an example embodiment of inventive concepts.

Referring to FIG. 1, a storage device 100 of this example includes a memory cell array 120 and a controller unit 110. The memory cell array 120 receives and stores data, i.e., first data D1 and second data D2 supplied from the controller unit 110.

The memory cell array 120 of this example includes a first memory 121 and a second memory 123. As will be explained below, the example of this embodiment is partially characterized by the first memory 121 and the second memory 123 having different memory structures. For example, the first memory 121 may be formed in a Charge Trap Flash (CTF) structure, and the second memory 123 may be formed in a in a floating gate (FG) structure. However, the inventive concepts are not limited to these specific structural examples.

FIG. 2 illustrates the case where the first memory is formed in a Charge Trap Flash (CTF) structure. As shown, a memory cell of first memory 121 includes a gate structure 20 formed on a semiconductor substrate 10. The semiconductor substrate 10 may be a silicon substrate, a glass substrate, or a plastic substrate. A charge supplying layer (not shown) may be formed in or on the semiconductor substrate 10. The charge supplying layer may be composed of compound semiconductor substance such as compound semiconductor substance of ZnO series or compound semiconductor substance including ZnO doped with Ga and In, i.e., GaInZn or GIZO.

The gate structure 20 may be formed on the semiconductor substrate 10 or the charge supplying layer. The gate structure 20 includes a tunnel insulation layer 21, a charge trap layer 23, a blocking insulation layer 25 and a control gate electrode layer 27.

The tunnel insulation layer 21 is for tunneling of a charge and may be formed so that it contacts a source region 15a and a drain region 15b formed in the semiconductor substrate 10 or the charge supplying layer. The tunnel insulation layer 21 may be composed of an oxide film, e.g., a SiO2 oxide film, a silicon nitride film or a double structure of an oxide film and a nitride film.

The charge trap layer 23 is a region where information storage is performed by charge trapping. The charge trap layer 23 may be formed so as to include one or more of poly silicon, nitride, dielectric material and nanodots.

The blocking insulation layer 25 is for blocking movement of a charge to an upper side, i.e., a control gate electrode layer 27, through the charge trap layer 23 and may be composed of an oxide film. For example, the blocking insulation layer 25 may be composed of SiO2 or a substance having higher permittivity than the tunnel insulation layer 23, e.g., Si3N4, Al203, HfO2, Ta2O5, or ZrO2. Moreover, the blocking insulation layer 25 may be formed into two or more layers including an insulation layer composed of an insulation substance such as SiO2 and high-dielectric layer composed of a substance having higher permittivity than the tunneling insulation layer 23.

The control gate electrode layer 27 may be composed of a metal film. For example, the control gate electrode layer 27 may be composed of a silicide substance (or material) such as aluminum (Al), Ru, TaN or NiSi and so on.

In the semiconductor substrate 10 or a charge supplying layer exposed by the gate structures 20, a source region 15a and a drain region 15b where impurity is doped may be formed. The source region 15a and the drain region 15b may be formed by a dopant process or a plasma handling process.

The first memory 121 may, for example, be embodied as a single level cell (SLC), i.e., it may be configured to program and store data input such that a single bit of data is stored in each memory cell.

FIG. 3 illustrates the example where the second memory 123 is formed in a floating gate (FG) structure. Referring 3, the second memory 123 includes a gate structure 30 formed on the semiconductor substrate 10.

The semiconductor substrate 10 may be the same as that illustrated in the CTF structure of FIG. 2. The semiconductor substrate 10 may further include a charge supplying layer (not shown).

The gate structure 30 of this example includes a tunnel insulation layer 31, a floating gate electrode layer 33 and a control gate electrode layer 37. The tunnel insulation layer 31 is for tunneling of charge, and may be formed so that it contacts the source region 15a and the drain region 15b formed in the semiconductor substrate 10 or the charge supplying layer. The tunnel insulation layer 31 may be composed of an oxide film, e.g., a SiO2 oxide film, a silicon nitride film or a double structure of an oxide film and a nitride film.

The floating gate electrode layer 33 is formed at upper side of the tunnel insulation layer 31 relative to the substrate 10. The floating gate electrode layer 33 may be formed into a signal layer or multiple layers (i.e., two or more layers). The blocking insulation layer 35 is formed between the floating gate electrode layer 33 and the control gate electrode layer 37. The blocking insulation layer 35 is for blocking movement of a charge to the control gate electrode layer 37 through the floating gate electrode layer 33 and it may be composed of an oxide film.

The control gate electrode layer 37 may be composed of a metal film. For example, the control gate electrode layer 37 may be composed of a silicide substance such as aluminum (Al), Ru, TaN or NiSi.

In the semiconductor substrate 10 or the charge supplying layer exposed by the gate structure 30, the source region 15a and the drain region 15b where impurity is doped may be formed. The source region 15a and the drain region 15b may be formed by a dopant process or a plasma handling process.

The second memory 123 may, for example, be embodied as a multi level cell (MLC), i.e., it may be configured to program and store data such that two or more bits of data are stored in each memory cell.

Referring to again to FIG. 1, the first memory 121 and the second memory 123 have different structures as described above in connection with the examples of FIGS. 2 and 3. In the example of this embodiment, the first memory 121 and the second memory 123 are embodied as different memory chips in the memory cell array 120.

The first memory 121 and the second memory 123 of the memory cell array 120 store first data D1 and second data D2, respectively, supplied from the controller unit 110 through a first output path P1 and a second output path P2.

Since the first memory 121 and the second memory 123 of the memory cell array 120 have different structures, they also exhibit different properties. For example, in the example of the present embodiment, the first memory 121 has favorable endurance properties which allow for execution of more program or erase operations relative to the second memory 123. On the other hand, the second memory 123 has favorable retention properties which allow for the storage of data for longer periods of time relative to the first memory 121.

In order to take advantage of the different properties of the first memory 121 and second memory 123, the controller unit 110 is configured to separate input data into the first data D1 and second data D2 according to one or more properties of the input data, e.g., an access frequency or size of the input data. In this manner, optimization of the storage device 100 may be achieved. For example, the first data D1 output from the controller unit 110 may be a system data such as a meta data which is accessed frequently and is thus associated with a relative high number of program or erase operations. On the other hand, the second data D2 output from the controller unit 110 may be user data such as a mass data or a file data, which has a significantly lower access frequency and is stored for relative long periods of time when compared to system data. In addition, user data tends to be much larger than system data.

In addition, in an example embodiment of the inventive concepts, the first memory 121 and the second memory 123 of the memory cell array 120 utilized different kinds of error correcting code (ECC) algorithms. For example, an ECC algorithm adapted to an error generating frequency or property of stored system data may be used in the first memory 121, while an ECC algorithm adapted to an error generating frequency or property of stored user data may be used in the second memory 123.

Still referring to FIG. 1, the controller unit 110 of the example of this embodiment includes a controller 111 and a buffer memory 113. The controller 111 receives data externally supplied input data (e.g., from an external host (not shown)), and separates or divides the input data into the first data D1 and the second data D2 according to a property of the input data. For example, as described above, the controller 111 may separate system input data as first data D1 from user input data as second data D2.

The first data D1 and the second data D2 are output to the buffer memory 113. The buffer memory 113 temporarily stores the data to be programmed to the memory cell array 120, i.e., the first data D1 and the second data D2.

The buffer memory 113 outputs the first data D1 and the second data D2, in response to a control signal CNT supplied from the controller 111, to the first memory 121 and the second memory 123 via the first data path P1 and the second data path P2, respectively. The buffer memory 113 may, for example, be formed of the same structure as the first memory 121 of the memory cell array 120, e.g., a CTF structure, or may be formed of a same structure as the second memory 123, e.g, an FG structure.

In the example of this embodiment, the controller 111 controls overall operations of the buffer memory 113, first memory 121, and the second memory 123. Thus, provision of a separate controller for the memory cell array 120 is unnecessary.

However, the inventive concepts are not limited to the above. For example, when the buffer memory 113 may be formed of other memory technologies such as Ferroelectrics Random Access Memory (FRAM), Phase-change Random Access Memory (PRAM), or Dynamic Random Access Memory (DRAM), and a separate controller may be provided for the memory cell array 120.

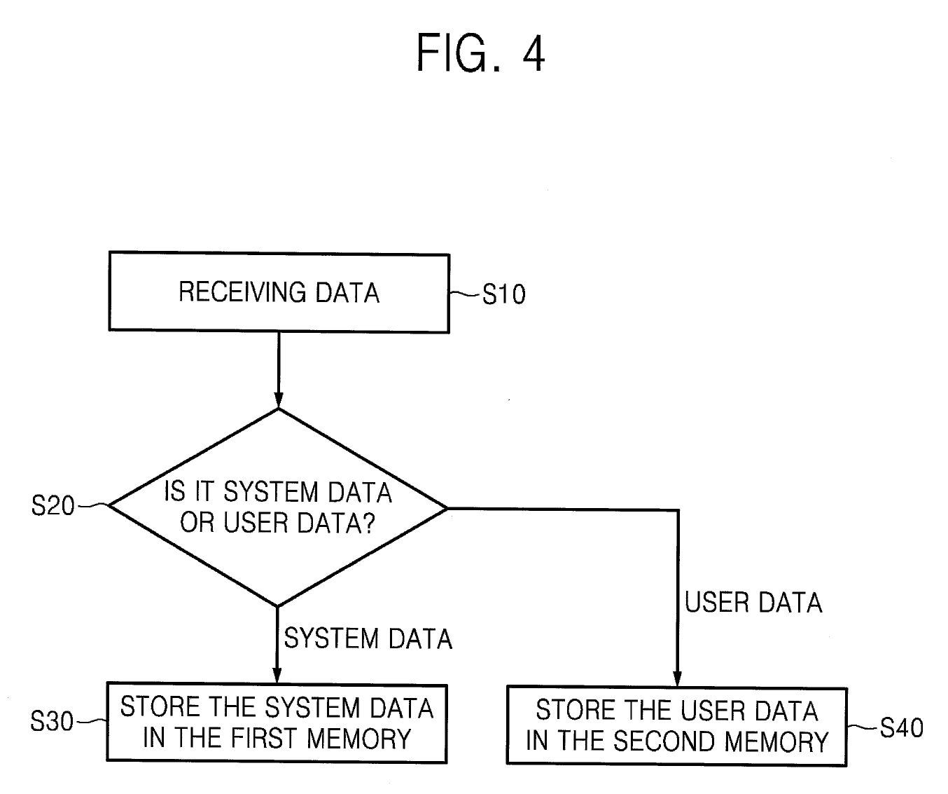

FIG. 4 is an operational flowchart of a storage device illustrated in FIG. 1 according to an example embodiment of the inventive concepts.

Referring to FIGS. 1 and 4, the controller unit 110 of the storage device 100 receives externally supplied input data (S10).

The controller 111 of the controller unit 110 determines whether the received input data is system data or user data (S20).

In the case where the input data is system data, the controller 111 temporarily stores the input data in the buffer memory 113, and then generates a control signal CNT to transmit the input data as first data D1 from the buffer memory 113 to the first memory 121 via the first data path P1. (S30)

In the case where the input data is user data, the controller 111 temporarily stores the input data in the buffer memory 113, and then generates a control signal CNT to transmit the input data as second data D2 from the buffer memory 113 to the second memory 123 via the second data path P2. (S40)

The storage device 100 of the inventive concepts may be implemented in a wide variety of packages.

For example, the storage device 100 may be embodied in Package on Package (PoP), Ball grid arrays (BGAs), Chip scale packages (CSPs), a Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flat Pack (TQFP), Small Outline (SOIC), Shrink Small Outline Packages (SSOP), Thin Small Outline (TSOP), System In Package (SIP), Multi Chip Package (MCP), Wafer-level Fabricated Package (WFP) and Wafer-Level Processed Stack Package (WSP) and so on.

Moreover, the storage device 100 of the inventive concepts may be used in a wide variety of applications. For example, the storage device 100 may be used in a computer system, a terminal device system, an input/output device system, a hard disk recorder (HDD recorder), a personal terminal such as a cellular phone or a personal digital assistant (PDA), a computer (PC, laptop PC, e-book, etc.), a navigator device, a home automation system, a music player (for example, MP3 player, or MP4 player etc.), a camcorder, an image player, a storage server, a portable multimedia player (PMP) or a Solid State Drive/Disk (SSD) and so on. Moreover, the storage device 100 may be embodied as a memory card or a smart card.

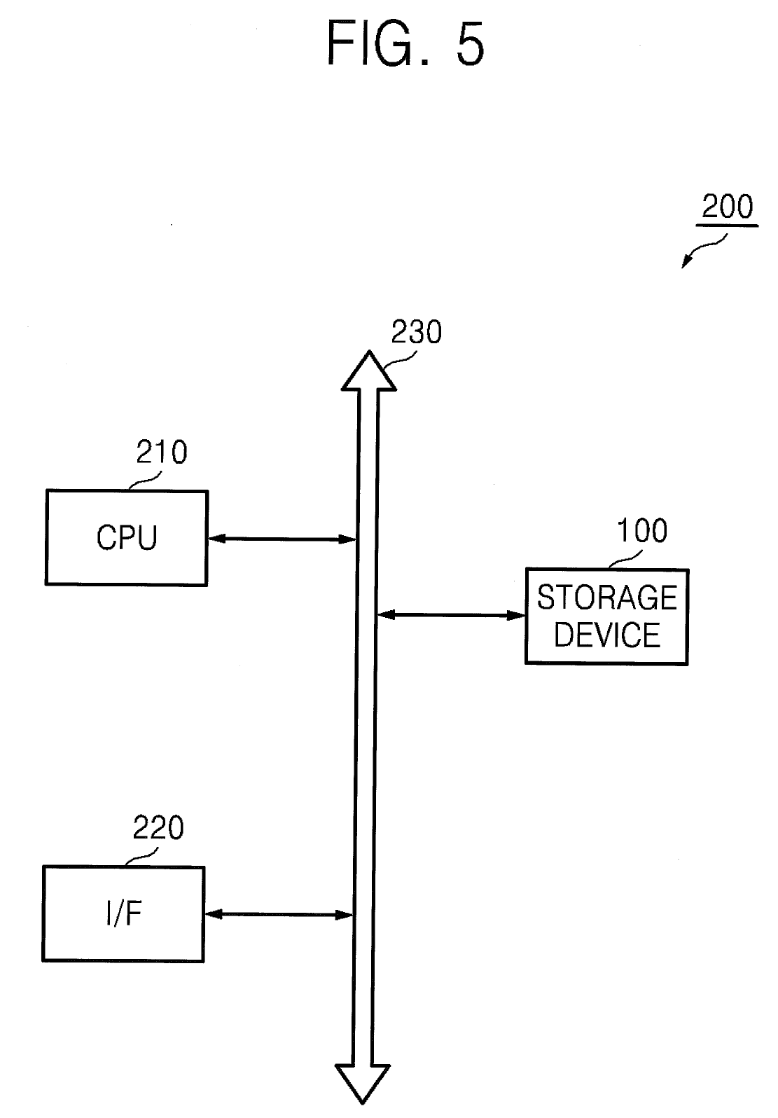

FIG. 5 is a schematic block diagram of a data storage system which includes a storage device illustrated in FIG. 1. The storage device 100 of embodiments of the inventive concepts may, for example, be used as a SSD.

Referring to FIG. 5, a data storage system 200 includes a bus 230, a central processing device (CPU) 210, a storage device 100 and an interface (I/F) 220. Although not illustrated, the data storage system 200 may further including a battery (not shown), particularly if the system 200 is portable. The CPU 210 generates a control signal capable of controlling an operation of the storage device 100 and supply a control signal to the storage device 100 through a bus 230.

The storage device 100 may be configured to include a memory cell array 120 and a controller unit 110 as explained above with reference to FIGS. 1 to 4, and an operation of the storage device 100 may be controlled according to a control signal supplied from the CPU 210. The storage device 100 receives input data from and supplies output data to the interface 220 via the bus 230. The interface 220 may be an input/output (I/O) interface and may be a wired or wireless interface. The interface 220 may also be used for exchange of data external the system 200.

Although a few embodiments of the inventive concepts have been shown and described, it will be appreciated by those skilled in the art that changes may be made in these embodiments without departing from the principles and spirit of the inventive concepts, the scope of which is defined in the appended claims and their equivalents.

What is claimed is:

1. A storage device comprising:
a controller unit which selectively outputs input data through a first data path or a second data path according to a property of the input data; and
a memory cell array which includes a first memory and a second memory, and which receives and stores the input data output by the controller unit through the first data path and the second data path, wherein the first memory has a different memory cell structure than the second memory, and
wherein the first memory has a charge trap flash (CTF) structure and the second memory has a floating gate (FG) structure.

2. The storage device of claim 1, comprising different error correcting code (ECC) algorithm schemes for the first memory and the second memory, respectively.

3. The storage device of claim 1, wherein the controller unit separates the input data into first input data and second input data according to the property of the input data,
wherein the first input data is output from the controller unit for storage in the first memory through the first data path and the second input data is output from the controller unit for storage in the second memory through the second data path.

4. The storage device of claim 3, wherein the first input data includes system input data and the second input data includes user input data.

5. The storage device of claim 1, wherein the property of the input data is an access frequency of the input data.

6. The storage device of claim 1, wherein the controller unit comprises:
a controller which separates the input data into first input data and second input data according to the property of the input data; and
a buffer memory which temporarily stores the first data and the second data separated by the controller, and which outputs the first data and the second data in response to a control signal output from the controller,
wherein the first data is output from the buffer memory to the first memory through the first data path and the second data is output from the buffer memory to the second memory through the second data path.

7. The storage device of claim 6, wherein the buffer memory has a same memory cell structure as the first memory or the second memory.

8. The storage device of claim 1, wherein the storage device is a solid state disk (SSD).

9. A data storage system comprising:
a data bus;
a storage device which receives input data and outputs output data through the data bus;
a CPU which controls an operation of the storage device; and
an interface, operative connected to the data bus, which transmits and receives external data;
wherein the storage device comprises:
a controller unit which selectively outputs the input data through a first data path or a second data path according to a property of the input data; and
a memory cell array which includes a first memory and a second memory, and which receives and stores the input data output by the controller unit through the first data path and the second data path, wherein the first memory has a different memory cell structure than the second memory.

10. The data storage system of claim 9, wherein the first memory has a charge trap flash (CTF) structure and the second memory has a floating gate (FG) structure.

11. The data storage system of claim 9, wherein the controller unit separates the input data into first input data and second input data according to the property of the input data,
wherein the first input data is output from the controller unit for storage in the first memory through the first data path and the second input data is output from the controller unit for storage in the second memory through the second data path.

12. The data storage system of claim 11, wherein the first input data includes system input data and the second input data includes user input data.

13. The data storage system of claim 9, wherein the first memory stores the input data in single level cell (SLC) memory cells and the second memory stores data in multi-level cell (MLC) memory cells.

14. The data storage system of claim 9, comprising different error correcting code (ECC) algorithm schemes for the first memory and the second memory, respectively.

15. The data storage system of claim 9, wherein the controller unit comprises:
a controller which separates the input data into first input data and second input data according to the property of the input data; and
a buffer memory which temporarily stores the first data and the second data separated by the controller, and which outputs the first data and the second data in response to a control signal output from the controller,
wherein the first data is output from the buffer memory to the first memory through the first data path and the second data is output from the buffer memory to the second memory through the second data path.

16. The data storage system of claim 15, wherein the buffer memory has a same memory cell structure as the first memory or the second memory.

17. The data storage system of claim 9, wherein the property of the input data is an access frequency of the input data.

18. The data storage system of claim 9, wherein the storage device is a solid state disk (SSD).
